(19) United States
(12) Patent Application Publication
(10) Pub. No.: US 2007/0170482 A1
(43) Pub. Date: Jul. 26, 2007

(54) Semiconductor storage device and manufacturing method thereof

(76) Inventor: Yoshiro Shimojo, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/390,257

(22) Filed: Mar. 28, 2006

(30) Foreign Application Priority Data
Jan. 11, 2006 (JP) 2006-003906

(51) Int. Cl. H01L 29/94

(52) U.S. Cl. 257/296

(57) ABSTRACT

A semiconductor storage device including a capacitor whose stored signal quantity is large with respect to its area share ratio, and a manufacturing method thereof are disclosed. According to one aspect of the present invention, it is provided a semiconductor storage device comprising a transistor formed on a semiconductor substrate, a capacitor which is formed above the transistor and includes a lower electrode, a dielectric film and an upper electrode, a semi-insulating layer formed in a side edge of the upper electrode and formed by locally transforming the upper electrode, an insulator formed to cover the capacitor, and a wiring line connected with the upper electrode.

### CROSS-REFERENCE TO RELATED APPLICATIONS

This application is based upon and claims the benefit of priority from prior Japanese Patent Application No. 2006-003906, filed Jan. 11, 2006, the entire contents of which are incorporated herein by reference.

### BACKGROUND OF THE INVENTION

1. Field of the Invention

The present invention relates to a semiconductor storage-device including a capacitor and a manufacturing method thereof.

2. Description of the Related Art

In order to miniaturize a semiconductor storage device including a capacitor, it is preferable to vertically form a side surface of the capacitor. In reality, however, a size of an upper electrode is formed to be small with respect to that of a lower electrode because of some disadvantages in etching processing of the capacitor electrode. For example, a dielectric film and an upper electrode on a lower electrode are formed to be smaller in stepwise as disclosed in Jpn. Pat. Appln. KOKAI Publication No. 2001-358316, or the capacitor is formed into a trapezoidal shape as disclosed in Jpn. Pat. Appln. KOKAI Publication No. 2001-257320. This processing is performed in order to prevent an etching by-product from being deposited on the side surface of the capacitor during the processing thereof. If the capacitor is vertically processed, then an etching by-product is deposited on the side surface of the capacitor. If the etching by-product is electrically conductive, then it can cause a leak current between the upper electrode and the lower electrode in the capacitor.

In the above-described capacitor having a configuration in which the lower electrode has a larger size than the upper electrode, an effective area of the capacitor is an area of the smaller upper electrode. Therefore, a signal quantity of the capacitor is smaller with respect to a lager area share ratio of the capacitor, which is not preferable for miniaturization.

Jpn. Pat. Appln. KOKAI Publication No. 2003-338608 discloses a technology that prevents an upper electrode and a lower electrode of a capacitor from being short-circuited due to an etching by-product deposited on a side surface thereof as described above. In this technology, the upper electrode alone or the upper electrode and a ferroelectric film in the capacitor are patterned first. Then, a protection film, e.g., a silicon oxide film or an alumina film is deposited on an entire surface, and then the protection film is anisotropically etched to leave on at least a side surface of the upper electrode. Subsequently, using the protection film and the upper electrode as a mask, the ferroelectric film and the lower electrode or the lower electrode alone is vertically etched. During the etching, even if an etching by-product is deposited on the side surface of the capacitor, since the protection film is formed on the side surface of the upper electrode, the upper electrode and the lower electrode are not short-circuited.

However, in the technology, since an area of the lower electrode is larger than that of the upper electrode by an amount corresponding to at least a thickness of the protection film, it cannot be said that the technology is suitable for miniaturization.

### BRIEF SUMMARY OF THE INVENTION

According to one aspect of the present invention, it is provided a semiconductor storage device comprising: a transistor formed on a semiconductor substrate; a capacitor which is formed above the transistor and includes a lower electrode, a dielectric film and an upper electrode; a semi-insulating layer formed in a side edge of the upper electrode and formed by locally transforming the upper electrode; an insulator formed to cover the capacitor; and a wiring line connected with the upper electrode.

According to another aspect of the present invention, it is provided a manufacturing method of a semiconductor storage device, comprising: forming a transistor on a semiconductor substrate; depositing a lower electrode material, a dielectric material and an upper electrode material for a capacitor above the transistor; patterning the upper electrode material to form an upper electrode of the capacitor; transforming a side edge of the upper electrode into semi-insulative; patterning the dielectric material and the lower electrode material in a self-aligned manner with respect to the upper electrode to form the capacitor; forming an insulator covering the capacitor; and forming a wiring line connected with the upper electrode.

### BRIEF DESCRIPTION OF THE SEVERAL VIEWS OF THE DRAWING

FIG. 1 shows an example of a cross section of a semiconductor storage device according to an embodiment of the present invention;

FIG. 2 is a schematic cross-sectional view of the semiconductor storage device for explaining an effect of the embodiment according to the present invention;

FIGS. 3A to 3E are process cross-sectional views illustrating an example of a manufacturing method of the semiconductor storage device according to the embodiment of the present invention;

FIG. 4 is a process cross-sectional view illustrating an example of a manufacturing method of a semiconductor storage device according to Modifications 1 and 2 of the present invention; and

FIG. 5 is a process cross-sectional view illustrating an example of a manufacturing method of a semiconductor storage device according to Modification 3 of the present invention.

### DETAILED DESCRIPTION OF THE INVENTION

The present invention discloses a semiconductor storage device including a capacitor whose stored signal quantity is large with respect to its area share ratio, and a manufacturing method thereof.

Some embodiments of the present invention will be described with reference to the accompanying drawings. Throughout the drawings, corresponding portions are denoted by corresponding reference numerals. Each of the following embodiments is illustrated as one example, and therefore the present invention can be variously modified and implemented without departing from the spirits of the present invention.

According to an embodiment of the present invention, a semiconductor storage device in which a leak current of the capacitor is suppressed and a manufacturing method thereof are provided by transforming a side edge portion of an upper electrode alone of a capacitor to be semi-insulative. Here, term “semi-insulation” means increasing a resistance value of the side edge portion of the upper electrode so that the leak current flowing through the side edge of the upper electrode is reduced to an extent that an operation of the semiconductor device is not obstructed, and also includes insulation. Although an allowable leak current value of the capacitor varies depending on a design and type of the semiconductor device, it is generally not greater than 0.01 A/cm². A resistance value of the side edge portion of the upper electrode which can realize such a low leak current is typically approximately 10⁸ Ω·cm or above.

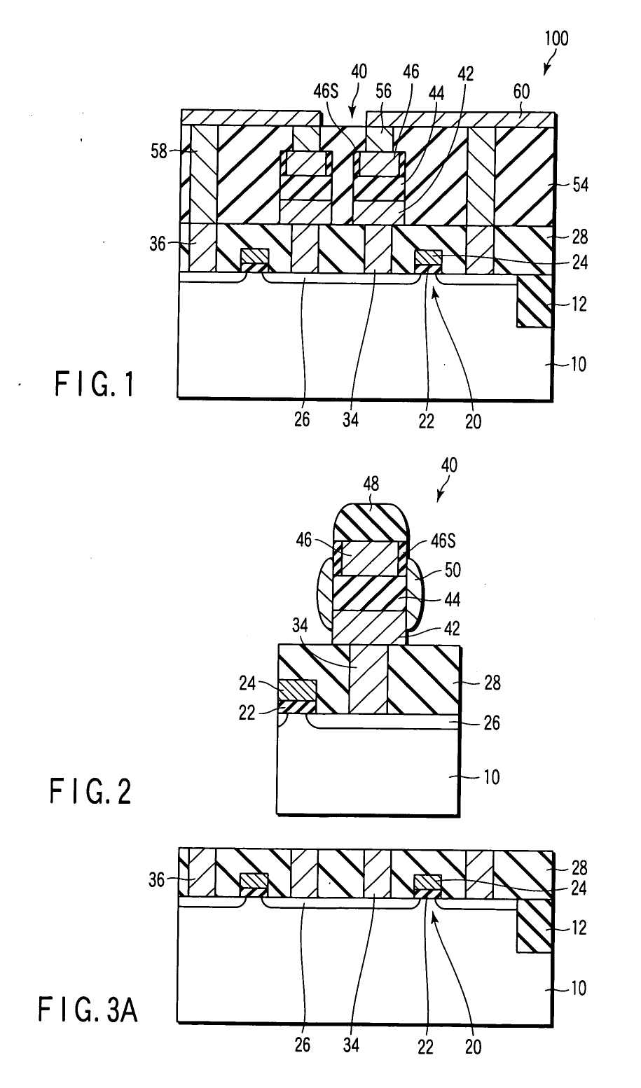

FIG. 1 shows an example of a cross section of a semiconductor storage device 100 according to an embodiment of the present invention. The semiconductor storage device 100 comprises a transistor 20 formed on a semiconductor substrate 10, a ferroelectric capacitor 40 formed above the transistor 20, and a wiring line 60 formed above the ferroelectric capacitor 40. The ferroelectric capacitor 40 includes a lower electrode 42, a ferroelectric film 44 and an upper electrode 46. In a side edge of the upper electrode 46, a semi-insulating layer 46S is formed by transforming a composition of the upper electrode 46. By making the upper electrode 46 in such a configuration, a side surface of the ferroelectric capacitor 40 can be vertically etched as shown in FIGS. 1 and 2. As shown in FIG. 2, even if an electroconductive etching by-product 50 is deposited on the side surface of the capacitor 40 during etching thereof, the upper electrode 46 and the lower electrode 42 are not short-circuited since the semi-insulating layer 46S is formed in the side edge of the upper electrode 46, thereby reducing a leak current of the ferroelectric capacitor 40. An effective area of the capacitor 40 is not substantially reduced since a thickness of the transformed semi-insulating layer 46S is thin.

Some of embodiments according to the present invention in which the side edge of the upper electrode of the ferroelectric capacitor is transformed into the semi-insulating layer will now be described hereinafter in detail, but the present invention is not limited thereto.

### Embodiment

An embodiment according to the present invention is a semiconductor storage device in which an electroconductive oxide is used for an upper electrode and a side edge portion of an upper electrode is transformed into semi-insulative by ion implantation, and a manufacturing method thereof. Specifically, a carrier killer is doped in the side edge alone of the upper electrode by ion implantation so that the side edge is transformed into semi-insulative.

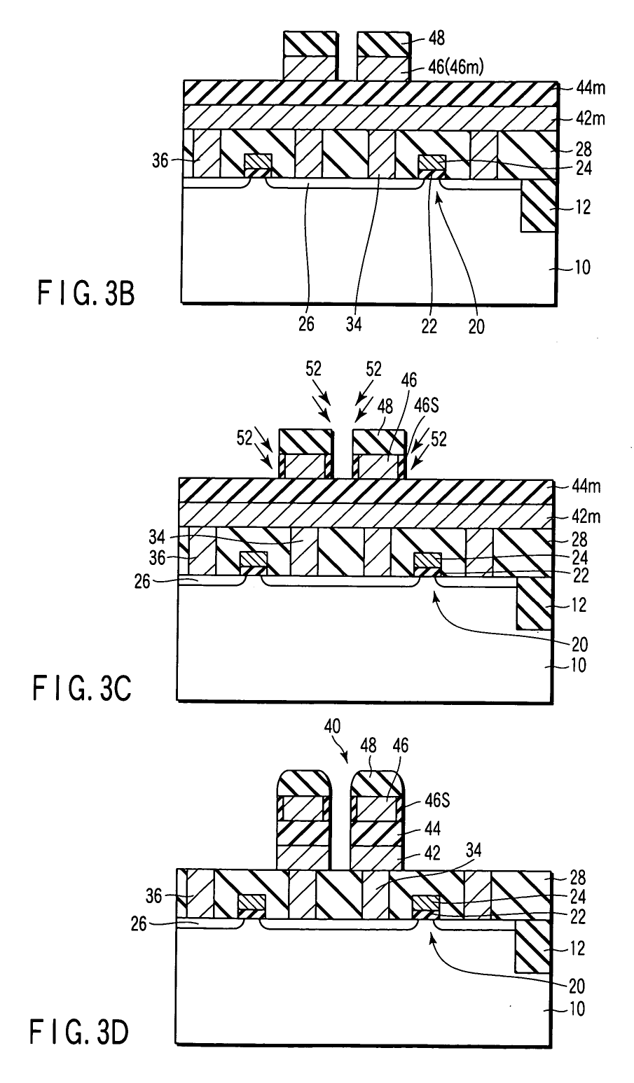

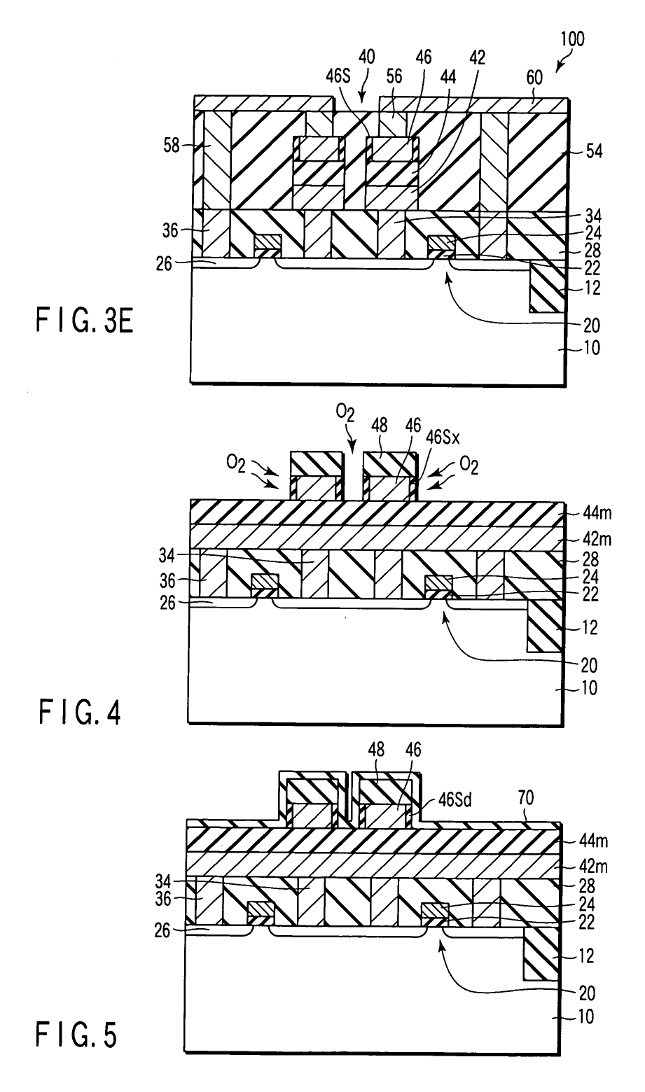

A manufacturing process of the semiconductor storage device 100 according to the embodiment will now be described with reference to FIGS. 3A to 3E.

Referring to FIG. 3A, an MOS transistor 20 is first formed on a semiconductor substrate 10, e.g., a silicon substrate.

A well (not shown) and an isolation 12 are formed in the semiconductor substrate 10, and a gate insulator 22 is formed on an entire surface of the semiconductor substrate 10. An electroconductive material for a gate electrode 24, e.g., phosphorous-doped polycrystal silicon is deposited on the gate insulator 22, and the electroconductive material is patterned into a gate electrode 24 by lithography and etching. A source/drain 26 is formed in the silicon substrate 10 by, for example, ion implanting arsenic (As) with a high concentration using the gate electrode 24 as a mask. In this manner, the MOS transistor 20 can be formed on the semiconductor substrate 10.

Then, a first interlevel insulator 28 is formed on an entire surface by, e.g., chemical vapor deposition (CVD), and the surface thereof is planarized by, e.g., chemical-mechanical polishing (CMP). Further, first and second contact plugs 34 and 36 reaching the source/drain 26 are formed in the first interlevel insulator 28.

In this manner, the structure shown in FIG. 3A is formed.

Then, referring to FIG. 3B, a lower electrode material 42m, a ferroelectric film material 44m and an upper electrode material 46m for a ferroelectric capacitor are sequentially deposited on an entire surface of the first interlevel insulator 28. As the lower electrode material 42m, it can be used, e.g., titanium aluminum nitride (TiAlN), titanium nitride (TiN), iridium (Ir), iridium oxide (IrO₂), platinum (Pt), strontium ruthenium oxide (SrRuO₃) or a laminated film of these materials. As the ferroelectric film material 44m, it can be used a metal oxide having a perovskite structure, e.g., plumbum zirconium titanate (PZT) or strontium bismuth tantalate (SBT). As the upper electrode material 46m, it can be used an electroconductive oxide, e.g., SrRuO₃, La_{2-x-y}CeₓSr_{y}CuO₄ or a laminated film of these materials. Here, a description will be given as to an example where SrRuO₃ is used. Then, a second insulator 48 is formed on an entire surface of the upper electrode material 46m. The second insulator 48 is used as a hard mask in a subsequent etching of the ferroelectric capacitor. Then, the second insulator 48 is patterned by lithography and etching to form a pattern of the ferroelectric capacitor above the first contact plug 34. After the upper electrode 46 alone is substantially vertically etched with the second insulator 48 being used as a mask, thus the structure shown in FIG. 3B can be formed.

Then, referring to FIG. 3C, a side edge of the upper electrode 46 is being transformed into semi-insulative. If an electroconductive oxide, e.g., SrRuO₃ is used as the upper electrode 46 as described above, the SrRuO₃ film can be transformed by replacing Ru with an appropriate carrier killer, e.g., titanium (Ti), thereby providing semi-insulative properties. When a dose of the carrier killer is increased, a higher resistance can be achieved. Since the upper electrode 46 is substantially formed vertically, a carrier killer 52, e.g., Ti is ion-implanted from an obliquely upper side as indicated by arrows in FIG. 3C so that the carrier killer 52 is doped into the side edge of the upper electrode 46. Since an upper surface of the upper electrode 46 is covered with the second insulator 48, the carrier killer, e.g., Ti is not doped thereto form upper side.

The doped carrier killer needs to be electrically activated by annealing. The activation annealing can be solely performed during the ferroelectric capacitor processing. Alternatively, any other thermal process after forming the ferroelectric capacitor can serve as the activation annealing. In this manner, the semi-insulating layer 46S can be formed in the side edge of the upper electrode 46.

As an example of an electroconductive oxide other than SrRuO which can be used for the upper electrode 46, there is La_{2-x-y}CeₓSr_{y}CuO₄. This material becomes insulative if x−y≈0. Thus, for example, a conductive La_{2-x-y}CeₓSr_{y}CuO₄ which does not contain Sr is first deposited as an upper electrode film by, e.g., sputtering. Like the above-described example, after the upper electrode 46 is patterned, Sr is ion-implanted into a side edge alone of the upper electrode 46 so that transformation is performed to achieve substantially x=y=1 at the side edge portion. By processing the upper electrode in this manner, it can be formed the semi-insulating layer 46S in the side edge of the upper electrode 46.

Thereafter, the ferroelectric film material 44mand the lower electrode material 42m are substantially vertically etched with the second insulator 48 and the upper electrode 46 being used as a mask, thereby forming the ferroelectric capacitor 40 above the first contact plug 34 as shown in FIG. 3D.

Then, referring to FIG. 3E, the second insulator 48 is removed as required, a second interlevel insulator 54 is thickly deposited on an entire surface to cover the ferroelectric capacitor 40, and the surface is planarized by, e.g., CMP. A third contact plug 56 reaching the upper electrode 46 and a fourth contact plug 58 reaching the second contact plug 36 are formed in the second interlevel insulator 54. Moreover, a wiring line 60 is formed to connect the third and fourth contact plugs 56 and 58, thereby forming the semiconductor storage device 100 shown in FIG. 3E.

Thereafter, processes required for the semiconductor device, e.g., multilevel wiring or the like are carried out to bring the semiconductor storage device 100 including the ferroelectric capacitor 40 according to the embodiment to completion.

During vertical etching of the ferroelectric capacitor 40, an etching by-product is often deposited on the side surface of the ferroelectric capacitor 40. Even if the etching by-product is electrically conductive, since the semi-insulating layer 46S is formed in the side edge of the upper electrode 46, the upper electrode 46 and the lower electrode 42 are not short-circuited. Alternatively, even if a current flows, the semi-insulating layer 46S can suppress the leak current to be very small so that the leak current does not affect an operation of the semiconductor device.

Semi-insulation of the side edge of the upper electrode 46 described above can be modified and carried out in many ways. The following describes such modifications, but the present invention is not limited thereto.

(Modification 1)

Modification 1 according to the present invention is a semiconductor storage device in which, e.g., oxygen is introduced into a side edge alone of an upper electrode 46 to transform the side edge, as shown in FIG. 4, so that a semi-insulating layer 46Sx is formed in the side edge of the upper electrode 46, and a manufacturing method thereof.

Here, a description will be mainly given as to transformation of the side edge of the upper electrode 46. An electroconductive material whose electroconductive properties can be controlled by introducing oxygen is, e.g., YBa₂Cu₃O_{7-d}. Electroconductive properties of this material vary depending on oxygen content. Specifically, the material is insulative when an oxygen concentration is close to a stoichiometric equilibrium concentration, that is d<0.7, and it is electroconductive when the oxygen concentration is d>0.7, where oxygen is insufficient. Thus, first, as an upper electrode material film, YBa₂Cu₃O_{7-d} having a composition of d>0.7 is formed by, for example, sputtering to control the oxygen concentration to be low, thereby providing electroconductive properties. As in the first embodiment, after the upper electrode 46 alone is patterned, oxygen is introduced into the side edge alone of the upper electrode 46 by thermal diffusion in a heat treatment in an oxidizing atmosphere, e.g., rapid thermal oxidation (RTO). As a result, a semi-insulating layer 46Sx can be formed in the side edge of the upper electrode 46. During the RTO, oxygen is not diffused into an upper surface of the upper electrode 46, since the upper surface is covered with a second insulator 48. When oxygen concentration is increased to an amount d=0, excessive oxygen may not be further introduced since it is the stoichiometric equilibrium concentration of YBa₂Cu₃O₇.

Oxygen can be also introduced by ion implantation like the first embodiment.

Then, a ferroelectric film 44 and a lower electrode 42 are substantially vertically etched with the upper electrode 46 being used as a mask, thereby forming a ferroelectric capacitor 40. Thereafter, the same processes as those in the first embodiment are carried out to bring the semiconductor storage device including the ferroelectric capacitor according to the modification to completion.

According to the modification, the method of transforming the side edge of the upper electrode 46 into semi-insulative by the RTO processing, oxygen can be also supplied to the ferroelectric film 44 during the heat treatment. As a result, characteristics of the ferroelectric film 44 can be also improved simultaneously, and hence this is an effective method.

(Modification 2)

Although the electroconductive oxide material is used as the upper electrode 46 in Modification 1, a metal material which can be relatively easily oxidized can be also used as the upper electrode 46.

Modification 2 according to the present invention is a semiconductor storage device in which a metal material is used for the upper electrode 46 and its side edge alone is introduced with oxygen, i.e., oxidized, to transform into a metal oxide like FIG. 4 so that a semi-insulating layer 46Sx is formed in the side edge of the upper electrode 46, and a manufacturing method thereof.

As a metal material which can be relatively easily oxidized, it can be used, e.g., aluminum (Al) or tungsten (W). If such a metal material is used, after the upper electrode 46 is patterned, the side edge of the upper electrode 46 is oxidized by a short-time oxidation method, e.g., RTO. As a result, the side edge alone of the upper electrode 46 can be transformed. Consequently, it can be formed a semi-insulating layer 46Sx consisting of a metal oxide, e.g., Al₂O₃ with a very thin thickness, e.g., several nm.

Since the method according to this modification which transforms the side edge of the upper electrode 46 by oxidation can also supply oxygen to a ferroelectric film 44 during the oxidation like modification 1. Therefore, it can also improve characteristics of the ferroelectric film 44, and it is an effective method.

(Modification 3)

Modification 3 according to the present invention is a semiconductor storage device in which impurities serving as a carrier killer are introduced into side edge alone of an upper electrode 46 by, e.g., solid-phase diffusion so that the side edge of the upper electrode 46 is transformed into semi-insulative, and a manufacturing method thereof.

An upper electrode material whose electroconductive properties can be controlled by solid-phase diffusion is, e.g., SrRuO₃ which is an electroconductive oxide. As described above in conjunction with the first embodiment, semi-insulation can be achieved by substituting Ti for Ru in SrRuO₃, for example.

As shown in FIG. 5, it will be specifically described to an example where SrRuO₃ is used for the upper electrode 46. As in the first embodiment, the upper electrode 46 alone is patterned. Then, a sacrificial film 70 which serves as a diffusion source of Ti, e.g., a Ti containing TEOS-SiO₂ or Al₂O₃ film, is formed on an entire surface by CVD or sputtering. Then, annealing is carried out to diffuse Ti into the side edge of the upper electrode 46, thereby transforming into a semi-insulating layer 46Sd. Then, the sacrificial film 70 is removed by, e.g., dry etching or wet etching. If the sacrificial film 70 is removed by anisotropic dry etching, then the sacrificial film 70 can be left on the side surface of the upper electrode 46. Additionally, according to this method, dry etching of the sacrificial film 70 and patterning of the ferroelectric film 44 and the lower electrode 42 can be continuously performed, and hence the method is effective for simplification of the manufacturing process.

Although it will not be described specifically, as a method of transforming the side edge of the upper electrode 46 into the semi-insulating layer 46S, there are dry processing like plasma doping, chemical processing and others.

As described above, the semi-insulating layer 46S can be formed in the side edge of the upper electrode 46 according to the present invention. As to transformation into the semi-insulating layer 46S, if an electroconductive oxide is used as the upper electrode 46, it can be utilized properties to gain or lose electrical conductivity by stoichiometrically changing a composition of the material. When the semi-insulating layer 46S is formed in the side edge of the upper electrode 46, a leak of the ferroelectric capacitor 40 cannot be substantially affected, even if an electroconductive etching by-product is formed on a vertically etched side surface of the ferroelectric capacitor 40.

Therefore, according to the present invention, it can be provided the semiconductor storage device including a capacitor whose stored signal quantity is large with respect to its area share ratio, and a manufacturing method thereof.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor storage device comprising:
a transistor formed on a semiconductor substrate;
a capacitor which is formed above the transistor and includes a lower electrode, a dielectric film and an upper electrode;
a semi-insulating layer formed in a side edge of the upper electrode and formed by locally transforming the upper electrode;
an insulator formed to cover the capacitor; and
a wiring line connected with the upper electrode.

2. The semiconductor storage device according to claim 1, wherein the transforming is achieved by ion implantation.

3. The semiconductor storage device according to claim 1, wherein the transforming is achieved by introduction of oxygen.

4. The semiconductor storage device according to claim 1, wherein the transforming is achieved by solid-phase diffusion.

5. The semiconductor storage device according to claim 1, wherein the upper electrode includes an electroconductive oxide.

6. The semiconductor storage device according to claim 5, wherein the transforming is achieved by changing a stoichiometrical composition of the electroconductive oxide.

7. The semiconductor storage device according to claim 5, wherein the electroconductive oxide is strontium ruthenium oxide, and the transforming is introducing titanium.

8. The semiconductor storage device according to claim 1, wherein the upper electrode is aluminum or tungsten, and the transforming is introducing oxygen.

9. The semiconductor storage device according to claim 1, wherein the dielectric film is a ferroelectric film.

10. The semiconductor storage device according to claim 1, wherein a side surface of the capacitor is vertical to a surface of the semiconductor substrate.

11. A manufacturing method of a semiconductor storage device, comprising:
forming a transistor on a semiconductor substrate;
depositing a lower electrode material, a dielectric material and an upper electrode material for a capacitor above the transistor;
patterning the upper electrode material to form an upper electrode of the capacitor;
transforming a side edge of the upper electrode into semi-insulative;
patterning the dielectric material and the lower electrode material in a self-aligned manner with respect to the upper electrode to form the capacitor;
forming an insulator covering the capacitor; and
forming a wiring line connected with the upper electrode.

12. The manufacturing method of a semiconductor storage device according to claim 11, wherein the transforming is ion implanting.

13. The manufacturing method of a semiconductor storage device according to claim 11, wherein the transforming is introducing oxygen.

14. The manufacturing method of a semiconductor storage device according to claim 11, wherein the transforming further comprises:
forming a sacrificial film on a side surface of the upper electrode, wherein the sacrificial film contains an element which changes electroconductive properties of the upper electrode; and
diffusing the element from the sacrificial film into the side edge of the upper electrode.

15. The manufacturing method of a semiconductor storage device according to claim 11, wherein the upper electrode includes an electroconductive oxide.

16. The manufacturing method of a semiconductor storage device according to claim 15, wherein the transforming is changing a stoichiometrical composition of the electroconductive oxide.

17. The manufacturing method of a semiconductor storage device according to claim 15, wherein the electroconductive oxide is strontium ruthenium oxide, and the transforming is introducing titanium.

18. The manufacturing method of a semiconductor storage device according to claim 11, wherein the upper electrode is aluminum or tungsten, and the transforming is introducing oxygen.

19. The manufacturing method of a semiconductor storage device according to claim 11, wherein the dielectric material is a ferroelectric material.

20. The manufacturing method of a semiconductor storage device according to claim 11, wherein a side surface of the capacitor is vertically patterned to a surface of the semiconductor substrate.
